(19) United States
(12) Patent Application Publication
(10) Pub. No.: US 2025/0331127 A1
(43) Pub. Date: Oct. 23, 2025

(54) HEAT DISSIPATION FAN WITH EXPANDABILITY

(71) Applicant: Dongguan Kimtech Electronics CO., LTD, Dongguan City (CN)

(72) Inventors: Li-Hui OU, Dongguan (CN); Hank Ching-Tsung CHEN, Dongguan (CN); Feng LIANG, Dongguan (CN)

(21) Appl. No.: 18/640,132

(22) Filed: Apr. 19, 2024

(51) Int. Cl. H05K 7/20; F04D 25/06

(52) U.S. Cl. CPC H05K 7/20172; F04D 25/0693

(57) ABSTRACT

A heat dissipation fan with expandability includes a frame, a driving unit, a fan blade, a plurality of universal serial buses, and a multiplex management unit. The universal serial buses are exposed on multiple sides of the frame. The multiplex management unit is electrically connected to the universal serial buses and the driving unit. The multiplex management unit enables each of the universal serial buses to implement as a first role and a second role at the same time. The first role is either a power inputter or a power outputter, and the second role is either a signal inputter or a signal outputter. Each of the universal serial buses can be connected to an expansion device. The heat dissipation fan can be in either a series configuration or a tree-like configuration, and the heat dissipation fan and the expansion device are independently controlled.

### FIELD OF THE INVENTION

The invention provides a heat dissipation fan, and more particularly a heat dissipation fan with expandability.

### BACKGROUND OF THE INVENTION

U.S. Pat. No. 10,736,232 discloses a fan that can be used as a relay node. The fan comprises a male connection port, a female connection port, a transmission line set connecting to the male connection port and the female connection port, a power acquisition unit and a signal processing unit. The male connection port is connected to a control source to receive a working power and a control signal. The female connection port can optionally connect to the male connection port of the other fan so that the fan is electrically connected to the other fan. The power acquisition unit is connected to the transmission line set in parallel to extract the working power and provide the working power to a driving unit. The signal processing unit is connected to the transmission line set to obtain the control signal. The signal processing unit outputs the control signal to the driving unit and serves as a relay node to output the control signal to the female connection port, so that the other fan connected to the fan can be controlled.

When the aforementioned fan is implemented with more than one, the fans cannot be controlled independently, and there is no ability to serve as an expansion device relay.

### SUMMARY OF THE INVENTION

A main object of the invention is to solve the problem that the existing heat dissipation fans do not have the ability to expand.

In order to achieve the above object, the invention provides a heat dissipation fan with expandability including a frame, a driving unit provided on the frame, a fan blade driven by the driving unit to rotate relative to the frame, a plurality of universal serial buses, and a multiplex management unit provided on the frame. The plurality of universal serial buses are exposed on multiple sides of the frame. The multiplex management unit is electrically connected to the plurality of universal serial buses and the driving unit. The multiplex management unit enables each of the plurality of universal serial buses to implement as a first role and a second role at the same time. The first role is either a power inputter or a power outputter, and the second role is either a signal inputter or a signal outputter. Each of the plurality of universal serial buses can be connected to an expansion device. The heat dissipation fan can be in either a series configuration or a tree-like configuration, and the heat dissipation fan and at least one expansion device are independently controlled.

In one embodiment, the frame includes four side walls, and at least two of the four side walls are respectively provided with at least one of the plurality of universal serial buses.

In one embodiment, the driving unit includes a circuit board provided on the frame, a control circuit provided on the circuit board, and a motor connected to the control circuit, the control circuit is electrically connected to the multiplex management unit.

In one embodiment, the heat dissipation fan includes a visual display unit provided on the frame, and the visual display unit is connected to the driving unit.

In one embodiment, the driving unit includes a thermal sensor connected to the control circuit.

In one embodiment, the driving unit has a device address.

In one embodiment, the multiplex management unit is a USB hub module.

Through the foregoing implementation of the invention, compared with the prior art, the invention has the following characteristics: each of the universal serial buses of the heat dissipation fan of the invention can be connected to an expansion device, the heat dissipation fan can be in either a series configuration or a tree-like configuration, and the heat dissipation fan and the at least one expansion device are independently controlled.

### BRIEF DESCRIPTION OF THE DRAWINGS

FIG. 1 is a perspective structural view of an embodiment of a heat dissipation fan of the invention.

FIG. 2 is a unit schematic diagram of an embodiment of the heat dissipation fan of the invention.

FIG. 3 is a first expanded implementation diagram of an embodiment of the heat dissipation fan of the invention.

FIG. 4 is a second expanded implementation diagram of an embodiment of the heat dissipation fan of the invention.

FIG. 5 is a perspective structural view of an expanded implementation of an embodiment of a heat dissipation fan set of the invention.

FIG. 6 is a third expanded implementation diagram of an embodiment of the heat dissipation fan of the invention.

FIG. 7 is a fourth expanded implementation diagram of an embodiment of the heat dissipation fan of the invention.

FIG. 8 is a schematic diagram of an implementation of an embodiment of the heat dissipation fan set of the invention.

### DETAILED DESCRIPTION OF THE PREFERRED EMBODIMENTS

The detailed description and technical content of the invention are described below with reference to the accompanying drawings.

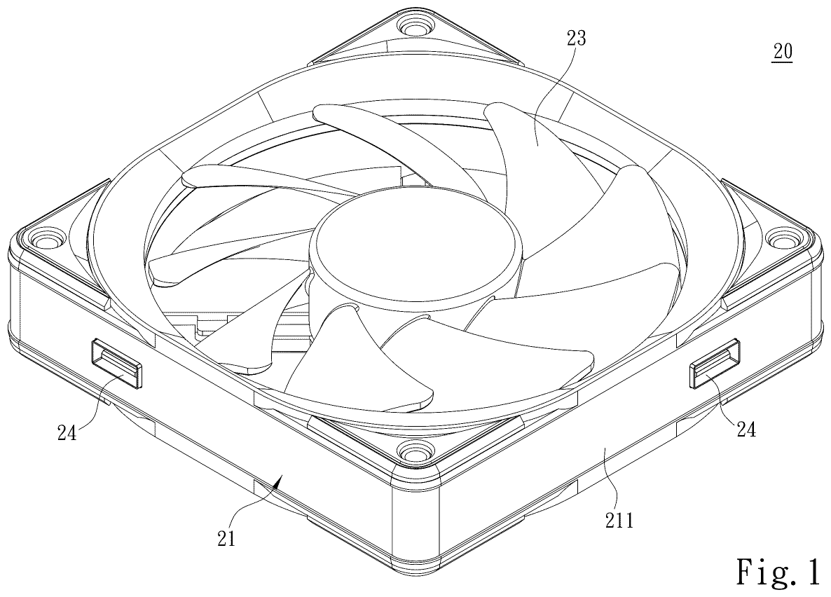

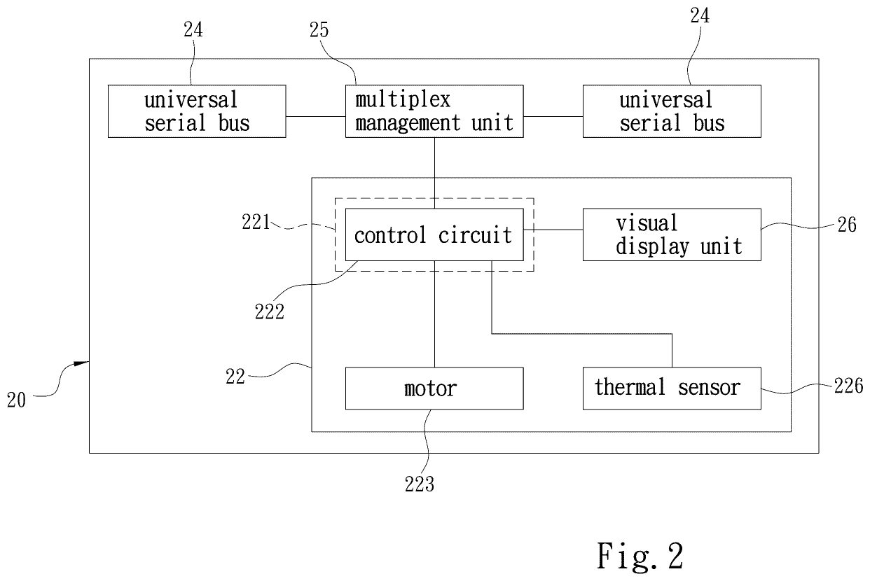

Please refer to FIG. 1 to FIG. 2. The invention provides a heat dissipation fan 20 with expandability. The heat dissipation fan 20 can be installed in a computer case or a power supply, or can be assembled with a computer component provided in the computer case. The computer case and the power supply are designed to comply with ATX specification or extended ATX specification. The computer component can be a graphics card, a CPU radiator or an expansion board implemented in PCI-E specification. The heat dissipation fan 20 includes a frame 21, a driving unit 22, a fan blade 23, a plurality of universal serial buses 24, and a multiplex management unit 25. The driving unit 22 is disposed on the frame 21, and the fan blade 23 is driven by the driving unit 22 to rotate relative to the frame 21 to generate air flow. The plurality of universal serial buses 24 are exposed on multiple sides of the frame 21. The plurality of universal serial buses 24 can be provided on the frame 21. Further, the frame 21 includes four side walls 211, and each of the four side walls 211 serves as one of the sides of the frame 21. In one embodiment, at least two of the four side walls 211 are respectively provided with at least one of the plurality of universal serial buses 24.

On the other hand, the multiplex management unit 25 can be a USB hub module, or a circuit capable of achieving functions same as the former. The multiplex management unit 25 is electrically connected to the plurality of universal serial buses 24 and the driving unit 22. The multiplex management unit 25 enables each of the plurality of universal serial buses 24 to serve as at least one of the following: the multiplex management unit 25 enables each of the plurality of universal serial buses 24 to implement as a first role and a second role at the same time, the first role is either a power inputter or a power outputter, and the second role is either a signal inputter or a signal outputter. Each of the plurality of universal serial buses 24 can be connected to an expansion device 40, and the expansion device 40 can be the other heat dissipation fan 20, a light-emitting component, a display component, or a holographic display component.

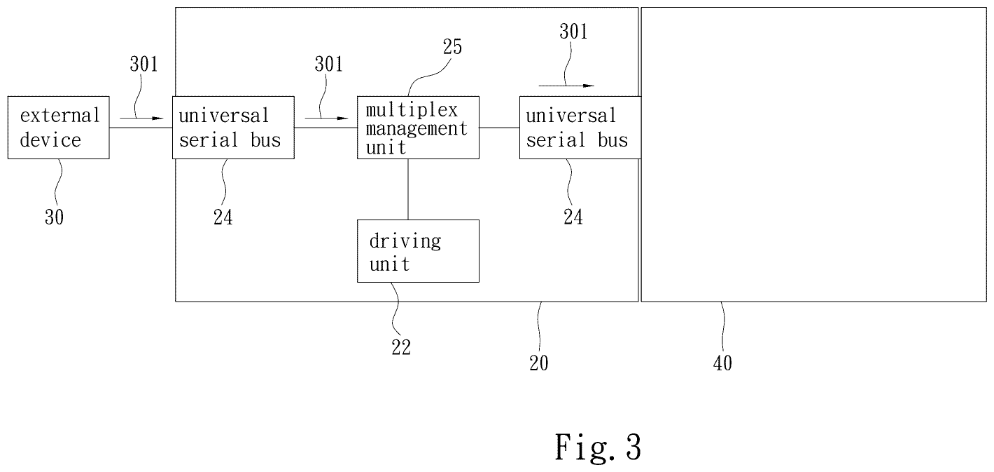

Please refer to FIG. 3. When one of the plurality of universal serial buses 24 is connected to a connection terminal of an external power supply, the multiplex management unit 25 enables one of the plurality of universal serial buses 24 to serve as the power inputter in for the heat dissipation fan 20, and the driving unit 22 obtains electric power required for operation from the multiplex management unit 25. At the same time, the multiplex management unit 25 enables a plurality of remaining universal serial buses 24 to serve as the power outputters to provide electric power to those (i.e., the expansion device 40) connected thereto. In one embodiment, one of the plurality of universal serial buses 24 is connected to an external device 30. In addition to outputting electric power, the external device 30 further provides at least one control signal 301 used to control an operation of the heat dissipation fan 20. At this time, one of the plurality of universal serial buses 24 connected to the external device 30 is implemented as the first role being the power inputter and the second role being the signal inputter according to control of the multiplex management unit 25. The multiplex management unit 25 receives the at least one control signal 301 from one of the plurality of universal serial buses 24 connected to the external device 30, and provides the at least one control signal 301 to the plurality of remaining universal serial buses 24 and the driving unit 22, the plurality of remaining universal serial buses 24 will be implemented in a mode of the first role being the power outputter and the second role being the signal outputter, and output the at least one control signal 301 to the expansion device 40 connected thereto. After receiving the at least one control signal 301, the driving unit 22 decides to abandon or continue with control based on a destination description of the at least one control signal 301.

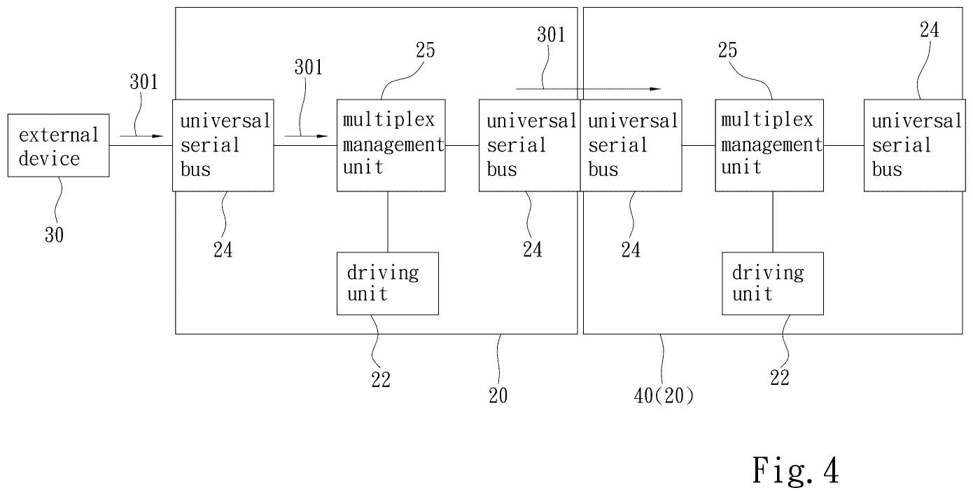

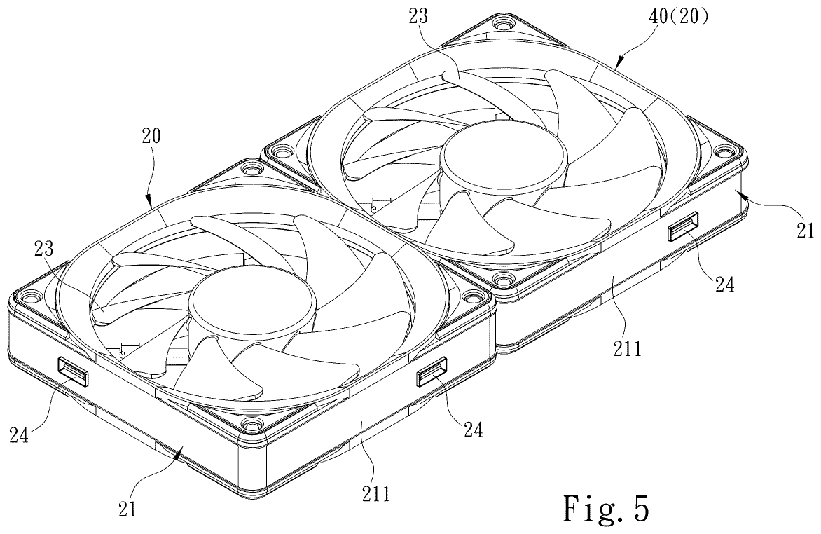

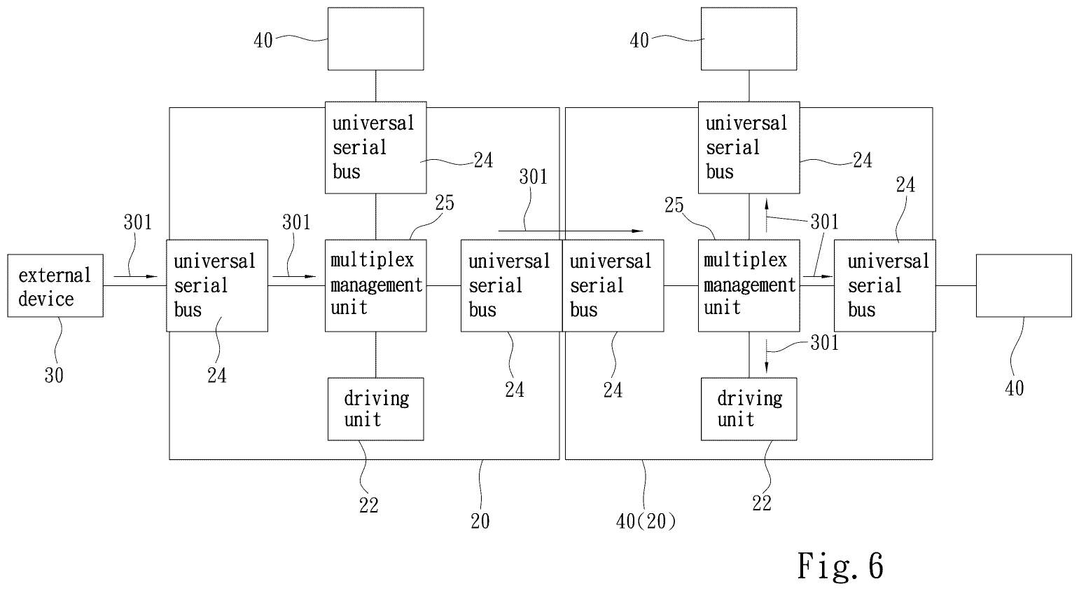

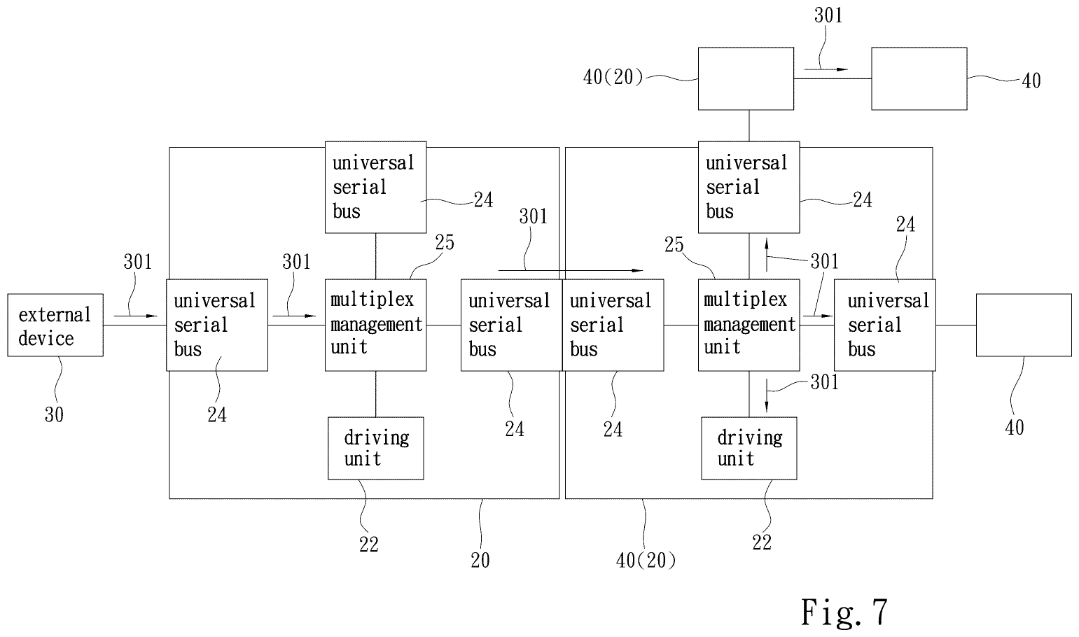

The heat dissipation fan 20 of the invention can be in either a series configuration or a tree-like configuration. In the embodiments disclosed in FIG. 4 and FIG. 5, the expansion device 40 is the other heat dissipation fan 20, and the two heat dissipation fans 20 constitute a series configuration. In the embodiment disclosed in FIG. 3, the expansion device 40 is a display. The expansion device 40 is connected to one of the plurality of universal serial buses 24 of the heat dissipation fan 20 and receives electric power and signals provided by the heat dissipation fan 20. In the embodiment disclosed in FIG. 6, in addition to the heat dissipation fan 20 being connected in series with the other heat dissipation fan 20, the heat dissipation fan 2 is connected to the other expansion device 40 via other one of the plurality of universal serial buses 24. The latter of the aforementioned heat dissipation fans 20 in a series relationship can also be connected to the other expansion device 40 to form a tree-like configuration. In the embodiment disclosed in FIG. 7, the heat dissipation fan 20 is connected to the expansion device 40. If the expansion device 40 is the heat dissipation fan 20 of the invention, it will not only be the expansion device 40, but also a connector for the other expansion devices 40 to form a tree-like configuration.

Through the above description, the invention enables the heat dissipation fan 20 to be used as a relay for expansion implementation. The heat dissipation fan 20 is independently controlled from the expansion device 40 through the multiplex management unit 25. In one embodiment, the driving unit 22 has a device address, and the device address is unique. Thereby ensuring that signals can be accurately transmitted or captured for use.

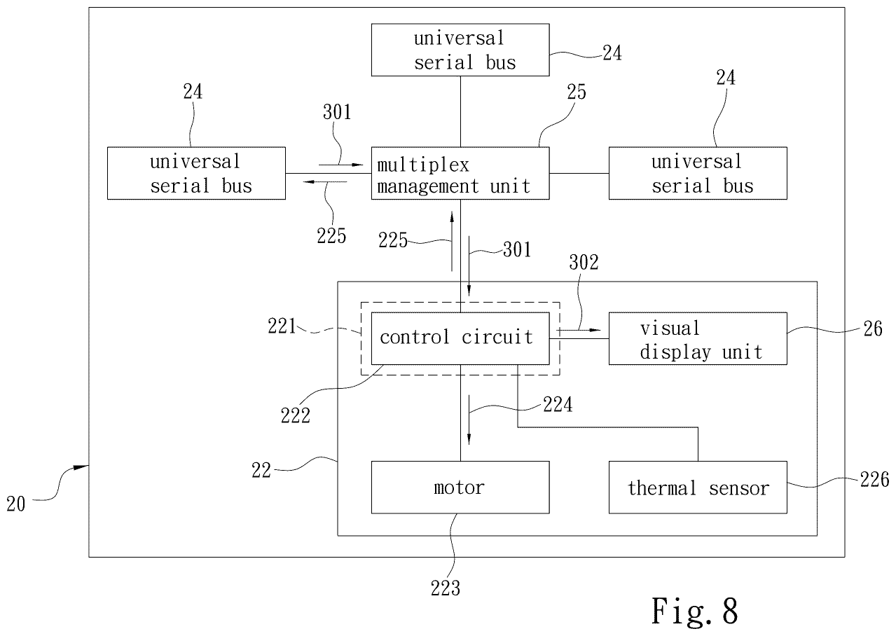

Please refer to FIG. 8. In one embodiment, the driving unit 22 includes a circuit board 221, a control circuit 222, and a motor 223. The circuit board 221 is fixed on the frame 21, the control circuit 222 is provided on the circuit board 221, and the control circuit 222 is electrically connected to the multiplex management unit 25. The motor 223 is connected to the control circuit 222, and the motor 223 operates based on a motor control signal 224 sent by the control circuit 222. Further, the control circuit 222 provides the motor control signal 224 to the motor 223 based on the at least one control signal 301 of a target address.

Please refer to FIG. 8. In one embodiment, the heat dissipation fan 20 includes a visual display unit 26. The visual display unit 26 can be one of the following: a luminescent light strip, an LED display, and a holographic display component, but is not limited to the above examples, anything that can produce visual effects can be regarded as the visual display unit 26 referred to in the invention. The visual display unit 26 is provided on the frame 21 and connected to the driving unit 22. The at least one control signal 301 received by the driving unit 22 can comprise at least one display control signal 302, and the at least one display control signal 302 is a basis for operation of the visual display unit 26.

Please refer to FIG. 8 again. In one embodiment, the driving unit 22 can return a status signal 225 to the multiplex management unit 25 based on description of the at least one control signal 301. The multiplex management unit 25 can then forward the status signal 225 based on its description to one of the plurality of universal serial buses 24 connected to the external device 30, and the status signal 5 225 is provided for the external device 30. In one embodiment, the driving unit 22 can further include a thermal sensor 226, the thermal sensor 226 is connected to the control circuit 222. The thermal sensor 226 senses an adjacent environment temperature provided for the control circuit 222 to control the motor 223 based on a sensing result, or to be added to a description of the status signal 225.

What is claimed is:

1. A heat dissipation fan with expandability comprising:
a frame;
a driving unit provided on the frame;
a fan blade driven by the driving unit to rotate relative to the frame;
a plurality of universal serial buses exposed on multiple sides of the frame; and
a multiplex management unit provided on the frame and electrically connected to the plurality of universal serial buses and the driving unit, the multiplex management unit enabling each of the plurality of universal serial buses to implement as a first role and a second role simultaneously, the first role being either a power inputter or a power outputter, the second role being either a signal inputter or a signal outputter;
wherein each of the plurality of universal serial buses is capable of being connected to an expansion device, the heat dissipation fan can be in either a series configuration or a tree-like configuration, and the heat dissipation fan and at least one expansion device are independently controlled.

2. The heat dissipation fan with expandability as claimed in claim 1, wherein the frame comprises four side walls, and at least two of the four side walls are respectively provided with at least one of the plurality of universal serial buses.

3. The heat dissipation fan with expandability as claimed in claim 1, wherein the driving unit comprises a circuit board provided on the frame, a control circuit provided on the circuit board, and a motor connected to the control circuit, the control circuit is electrically connected to the multiplex management unit.

4. The heat dissipation fan with expandability as claimed in claim 3, wherein the heat dissipation fan comprises a visual display unit provided on the frame, and the visual display unit is connected to the driving unit.

5. The heat dissipation fan with expandability as claimed in claim 3, wherein the driving unit comprises a thermal sensor connected to the control circuit.

6. The heat dissipation fan with expandability as claimed in claim 3, wherein the driving unit comprises a device address.

7. The heat dissipation fan with expandability as claimed in claim 3, wherein the multiplex management unit is a USB hub module.
